(19) United States
(12) Patent Application Publication
(10) Pub. No.: US 2026/0118785 A1
(43) Pub. Date: Apr. 30, 2026

(54) IMPRINT METHOD, IMPRINT APPARATUS AND ARTICLE MANUFACTURING METHOD

(71) Applicant: CANON KABUSHIKI KAISHA, Tokyo (JP)

(72) Inventor: MASATO SHICHIJO, Tochigi (JP)

(21) Appl. No.: 19/364,154

(22) Filed: Oct. 21, 2025

(30) Foreign Application Priority Data
Oct. 29, 2024 (JP) 2024-190073

(51) Int. Cl. G03F 9/00; B29C 43/18; B29C 43/58; G03F 7/00

(52) U.S. Cl. CPC G03F 9/7042; B29C 43/18; B29C 43/58; G03F 7/0002

(57) ABSTRACT

An imprint method of forming, using a mold, a pattern on an imprint material arranged on at least one layer formed on a substrate, including obtaining gas information about a gas in a storage space that stores the substrate, deciding, based on the gas information obtained in the obtaining, a value of a control parameter for controlling exposure of irradiating the imprint material with light in a state in which the mold and the imprint material on the at least one layer on the substrate stored in the storage space are in contact, and performing the exposure in accordance with the value of the control parameter decided in the deciding.

### BACKGROUND

### Field of the Technology

The present disclosure relates to an imprint method, an imprint apparatus and an article manufacturing method.

### Description of the Related Art

As one of lithography apparatuses for manufacturing a device, there is an imprint apparatus that performs an imprint process of bringing a mold into contact with an imprint material on a substrate and curing the imprint material, thereby forming a pattern formed by a cured product of the imprint material. The imprint process includes a contact step of bringing an imprint material on a substrate and a mold into contact with each other, an alignment step of aligning the mold and the substrate after the contact step, and a curing step of curing the imprint material after the alignment step. Before the imprint process is performed, an underlying layer and an adhesion layer are arranged (applied) on the substrate.

Concerning the imprint apparatus, Japanese Patent Laid-Open No. 2021-190595 proposes a technique for reducing a relative vibration between the mold and the substrate in a state (contact state) in which the imprint material on the substrate and the mold are in contact with each other. Japanese Patent Laid-Open No. 2021-190595 discloses an imprint apparatus including an adjusting unit that adjusts the viscosity of the imprint material, and a control unit that changes a parameter value for controlling the adjusting unit in accordance with a change of control information for controlling the alignment operation between the mold and the substrate in the contact state.

In the imprint apparatus, in the alignment step, the imprint material is irradiated with light in a wavelength band with a light absorption sensitivity, and the viscosity of the imprint material is thus increased, thereby performing so-called preliminary exposure for reducing the relative vibration between the mold and the substrate. Here, if a substrate with an underlying layer or an adhesion layer arranged thereon is stored in a storage space, and the oxygen density in the storage space is high, oxygen is occluded in the underlying layer or the adhesion layer, curing of the imprint material is impeded, and the viscosity of the imprint material cannot be sufficiently increased in preliminary exposure. As a result, the relative vibration between the mold and the substrate cannot be reduced as intended, and the alignment accuracy between the mold and the substrate lowers.

### SUMMARY

The present disclosure provides a technique advantageous in aligning a mold and a substrate.

According to one aspect of the present disclosure, there is provided an imprint method of forming, using a mold, a pattern on an imprint material arranged on at least one layer formed on a substrate, including obtaining gas information about a gas in a storage space that stores the substrate, deciding, based on the gas information obtained in the obtaining, a value of a control parameter for controlling exposure of irradiating the imprint material with light in a state in which the mold and the imprint material on the at least one layer on the substrate stored in the storage space are in contact, and performing the exposure in accordance with the value of the control parameter decided in the deciding.

Further aspects of the present disclosure will become apparent from the following description of exemplary embodiments with reference to the attached drawings.

### BRIEF DESCRIPTION OF THE DRAWINGS

FIG. 1 is a schematic view illustrating configurations of an imprint system.

FIG. 2 is a schematic view illustrating configurations of an imprint system.

FIG. 3 is a schematic view illustrating configurations of a light source unit.

FIG. 4 is a view for describing an example of a variation of a relative vibration between a mold and a substrate.

FIG. 5 is a view for describing an example of a variation of a relative vibration between a mold and a substrate.

FIG. 6 is a flowchart for describing the operation of the imprint system.

FIGS. 7A and 7B are views illustrating an example of gas information and the values of control parameters displayed on a user interface.

FIGS. 8A to 8F are views for describing an article manufacturing method.

### DESCRIPTION OF THE EMBODIMENTS

Hereinafter, embodiments will be described in detail with reference to the attached drawings. Note, the following embodiments are not intended to limit the scope of the claimed disclosure. Multiple features are described in the embodiments, but limitation is not made a disclosure that requires all such features, and multiple such features may be combined as appropriate. Furthermore, in the attached drawings, the same reference numerals are given to the same or similar configurations, and redundant description thereof is omitted.

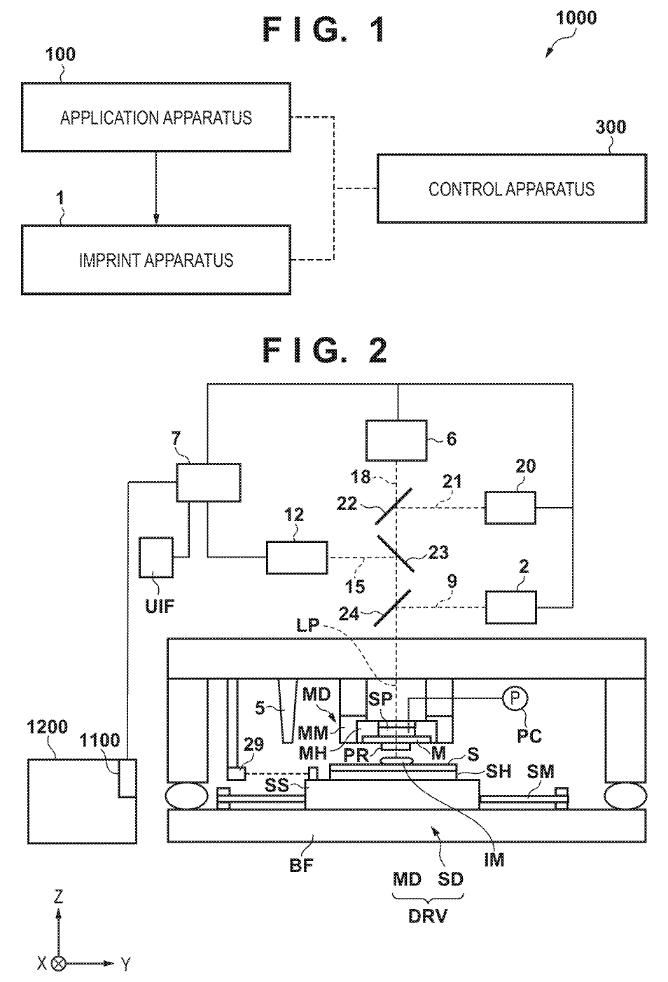

FIG. 1 is a schematic view illustrating configurations of an imprint system 1000. The imprint system 1000 is a system that forms a pattern on an imprint material on a substrate. The imprint system 1000 includes an application apparatus 100, a control apparatus 300, and an imprint apparatus 1.

The application apparatus 100 includes, for example, a spin coater and forms (applies) at least one layer on a substrate surface (on a substrate). The at least one layer formed on the substrate includes an underlying layer containing spin on carbon (SOC), and an adhesion layer that improves the adhesion between the imprint material and the substrate. The adhesion layer is formed on, for example, the underlying layer.

The control apparatus 300 is formed by, for example, a computer (information processing apparatus) including a CPU and a memory (storage unit). The control apparatus 300 generally controls the units of the imprint system 1000, that is, the application apparatus 100 and the imprint apparatus 1, thereby operating the imprint system 1000.

The imprint apparatus 1 is a lithography apparatus that is employed in a lithography step as a step of manufacturing a device such as a semiconductor element, a liquid crystal display element, or a magnetic storage medium as that is an article, and forms a pattern on a substrate. The imprint apparatus 1 brings an imprint material arranged (supplied) on a substrate into contact with a mold, and applies curing energy to the imprint material, thereby forming a pattern of a cured product to which the pattern of the mold is transferred.

As the imprint material, a material (curable composition) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25°C) of the imprint material is, for example, 1 mPa⋅s (inclusive) to 100 mPa⋅s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to a surface on which a substrate is arranged are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. Control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information specified based on coordinates on the X-, Y-, and Z-axes, and a posture is information be specified by values on the θX-, θY-, and θZ-axes.

Positioning (alignment) between a mold and a substrate includes controlling the position and/or posture of at least one of the substrate and the mold. Alignment includes control to correct or change the shape of at least one of the mold and the substrate.

FIG. 2 is a schematic view illustrating configurations of the imprint apparatus 1. In this embodiment, the imprint apparatus 1 performs an imprint process of forming, using a mold M, a pattern on an imprint material IM arranged on at least one layer formed on a substrate S. The imprint process includes a contact step of bringing the imprint material IM on the substrate S into contact with the mold M, and an alignment step of aligning the mold M and the substrate S after the contact step. Also, the imprint process includes a curing step of curing the imprint material IM on the substrate S after the alignment step, and a mold release step of releasing (separating) the mold M from the cured imprint material IM on the substrate S after the curing step.

The imprint apparatus 1 can include a substrate driving mechanism SD that holds and drives the substrate S, a base frame BF that supports the substrate driving mechanism SD, and a mold driving mechanism MD that holds and drives the mold M. The substrate driving mechanism SD and the mold driving mechanism MD form a driving mechanism DRV that drives at least one of the substrate driving mechanism SD and the mold driving mechanism MD to adjust the relative position between the substrate S and the mold M. Adjustment of the relative position between the mold M and the substrate S by the driving mechanism DRV includes driving for bringing the mold M into contact with the imprint material IM on the substrate S and separating the mold M from the cured imprint material IM (a pattern of a cured product) on the substrate S.

The substrate driving mechanism SD includes, for example, a substrate holder SH that holds the substrate S, a substrate stage SS that supports the substrate holder SH, and a substrate driving actuator SM that drives the substrate stage SS (substrate S). The substrate driving mechanism SD is configured to drive the substrate S in a plurality of axes (for example, three axes of the X-axis, the Y-axis, and the θZ-axis, and preferably six axes of the X-axis, the Y-axis, the Z-axis, the θX-axis, the θY-axis, and the θZ-axis). The position and posture of the substrate S are controlled based on the measurement result of a substrate measuring unit 29 that measures the position and posture of the substrate S under the control of a controller 7.

The mold driving mechanism MD includes a mold holder MH that holds the mold M, and a mold driving actuator MM that drives the mold holder MH (mold M). The mold holder MH can include a mold deformation mechanism that deforms the mold M. The mold deformation mechanism deforms the mold M by, for example, applying a force to the side surface of the mold M. The mold driving mechanism MD is configured to drive the mold M in a plurality of axes (for example, three axes of the Z-axis, the θX-axis, and the θY-axis, and preferably six axes of the X-axis, the Y-axis, the Z-axis, the θX-axis, the θY-axis, and the θZ-axis).

The mold M includes a pattern region PR where a pattern to be transferred to the imprint material IM on the substrate S by the imprint process is formed. The mold driving mechanism MD includes a pressure adjusting unit PC that adjusts the pressure in a space SP on the back surface side (the opposite side of the pattern region PR) of the mold M to deform (the pattern region PR of) the mold M into a convex shape toward the substrate S, and flatten the mold M, or the like. For example, the pressure adjusting unit PC adjusts the pressure in the space SP such that bringing the imprint material IM on the substrate S into contact with the pattern region PR is started in a state in which the mold M is deformed into a convex shape toward the substrate S, and the contact region between the imprint material IM and the pattern region PR gradually increases.

The imprint apparatus 1 includes a dispenser 5 that arranges (supplies or applies) the imprint material IM on the substrate S. However, the imprint material IM may be arranged on the substrate S in an external apparatus of the imprint apparatus 1.

The imprint apparatus 1 includes a curing light source unit 2 that irradiates, via an optical path LP, the imprint material IM between the substrate S and (the pattern region PR of) the mold M with curing light 9 for curing the imprint material IM in the curing step. The optical path LP is an optical path leading to the substrate S via the mold M and the imprint material IM.

The imprint apparatus 1 further includes a position measuring unit 12 that measures the relative position between an alignment mark provided in the substrate S and an alignment mark provided in the mold M. The position measuring unit 12 illuminates the alignment mark provided in the substrate S and the alignment mark provided in the mold M with illumination light 15 and captures an image formed by these alignment marks. The illumination light 15 is light with which the optical path LP is irradiated, like the curing light 9.

The imprint apparatus 1 further includes an image capturing unit 6 configured to detect (obtain) the contact state between the imprint material IM on the substrate S and (the pattern region PR of) the mold M or the filling state of the imprint material IM with respect to the space between the substrate S and (the pattern region PR of) the mold M. In addition, the image capturing unit 6 is also used to detect a foreign substance between the substrate S and the mold M. The image capturing unit 6 illuminates a stacked structure formed by the substrate S, the imprint material IM, and the mold M with observation light 18 and obtains an image formed by the stacked structure. The observation light 18 is light with which the optical path LP is irradiated, like the curing light 9 and the illumination light 15.

The imprint apparatus 1 further includes a light source unit 20 that irradiates the optical path LP with modulated light 21. As will be described later, the light source unit 20 includes a spatial light modulator, and irradiates the optical path LP with the modulated light 21 that is light modulated by the spatial light modulator. The modulated light 21 includes first modulated light that partially cures the imprint material IM, and second modulated light that deforms the substrate S for alignment between the substrate S and the mold M. It is preferable that the optical path LP is not irradiated with the second modulated light when the optical path LP is irradiated with the first modulated light, and the optical path LP is not irradiated with the first modulated light when the optical path LP is irradiated with the second modulated light. However, the optical path LP may be irradiated with both the first modulated light and the second modulated light in a sufficiently short period during the period in which the optical path LP is irradiated with the modulated light 21. The first modulated light and the second modulated light are light beams whose wavelength ranges do not overlap each other. Alternatively, the first modulated light and the second modulated light may be light beams having peaks at different wavelengths.

The first modulated light has a wavelength that cures the imprint material IM, more specifically, a wavelength which increases the viscosity (viscosity or viscoelasticity) of the imprint material IM. The first modulated light is light modulated so as to increase the viscosity of the imprint material IM in an arbitrary portion of a shot region (pattern formation region) of the substrate S, thereby increasing the bonding force between the substrate S and the mold M by the imprint material IM. Irradiating the imprint material IM with the first modulated light (exposure) is referred to as preliminary exposure (damping exposure). The preliminary exposure is performed in parallel to the alignment step and contributes to improvement of the alignment accuracy between the mold M and the substrate S. In a state in which the bonding force between the substrate S and the mold M by the imprint material IM is weak (before irradiation of the first modulated light), the substrate S and the mold M individually vibrate due to disturbance or the like (that is, the relative vibration between the substrate S and the mold M is large). By irradiating the imprint material IM with the first modulated light to partially increase the viscosity of the imprint material IM and increase the bonding force between the substrate S and the mold M, it is possible to reduce the relative vibration between the substrate S and the mold M, thereby improving the convergence of alignment. For example, increasing the viscosity of the imprint material IM by irradiation of the first modulated light such that the magnitude of the shear force generated by relative movement between the substrate S and the mold M falls within the range of 0.5 N to 1.0 N is effective to improve the convergence of alignment. Note that compared to preliminary exposure, a curing step of completely curing the imprint material IM by irradiating the imprint material IM on the substrate S with the curing light 9 is called actual exposure.

The second modulated light is light having a wavelength that does not cure the imprint material IM. The second modulated light is light modulated so as to form, on the substrate, a light intensity distribution (illuminance distribution) which deforms the substrate S, more specifically, the shot region of the substrate S into a target shape. By irradiating the substrate S with the second modulated light, a temperature distribution is formed on the substrate S, and this temperature distribution deforms the shot region of the substrate S into the target shape. When the shot region of the substrate S is deformed into the target shape, and the alignment between the shot region of the substrate S and the pattern region PR of the mold M is completed, the curing step of irradiating the imprint material IM with the curing light 9 from the curing light source unit 2 to cure the imprint material IM is executed.

The optical axes of the curing light source unit 2, the position measuring unit 12, the image capturing unit 6, and the light source unit 20 share the optical path LP. To implement this, a combining mirror 22 and dichroic mirrors 23 and 24 are provided. The combining mirror 22 transmits the observation light 18 but reflects the modulated light 21. The dichroic mirror 23 transmits the observation light 18 and the modulated light 21 but reflects the illumination light 15. The dichroic mirror 24 transmits the observation light 18, the modulated light 21, and the illumination light 15 but reflects the curing light 9.

The imprint apparatus 1 further includes a user interface UIF. The user interface UIF includes, for example, an input unit such as a keyboard used by a user (manager) to perform a command input operation to manage the imprint apparatus 1, and an output unit such as a display device that visualizes various kinds of information (for example, an operation state) of the imprint apparatus 1 and displays these. In addition, the user interface UIF may be formed by a touch panel having the functions of both the input unit and the output unit, or may include a sound output device such as a speaker.

The imprint apparatus 1 further includes a substrate storage space 1200 and a gas detector 1100. The substrate storage space 1200 is a space in which the substrate S with at least one layer formed thereon by the application apparatus 100 is contained and stored, and is defined (embodied) by, for example, a FOUP or a chamber. The gas detector 1100 is arranged inside the substrate storage space 1200 (in the substrate storage space) and functions as an obtaining unit that obtains gas information about a gas in the substrate storage space. The gas detector 1100 includes, for example, a gas sensor that detects a gas type, a gas density meter that detects a gas density, and the like, and obtains, as gas information, the type of a gas in the substrate storage space and the density of the gas in the substrate storage space.

The imprint apparatus 1 further includes the controller 7 that controls the driving mechanism DRV, the pressure adjusting unit PC, the dispenser 5, the substrate measuring unit 29, the curing light source unit 2, the position measuring unit 12, the image capturing unit 6, the light source unit 20, the user interface UIF, the gas detector 1100, and the like. The controller 7 is formed from, for example, a Programmable Logic Device (PLD) such as a Field Programmable Gate Array (FPGA), an Application Specific Integrated Circuit (ASIC), a general-purpose or dedicated computer installed with a program, or a combination of all or some of these components.

The controller 7 generally controls the units of the imprint apparatus 1 in accordance with a program, thereby operating the imprint apparatus 1. The controller 7 controls the imprint process of forming a pattern on the imprint material IM on the substrate S using the mold M, and processes associated with the imprint process. Note that the controller 7 may be integrated with the control apparatus 300.

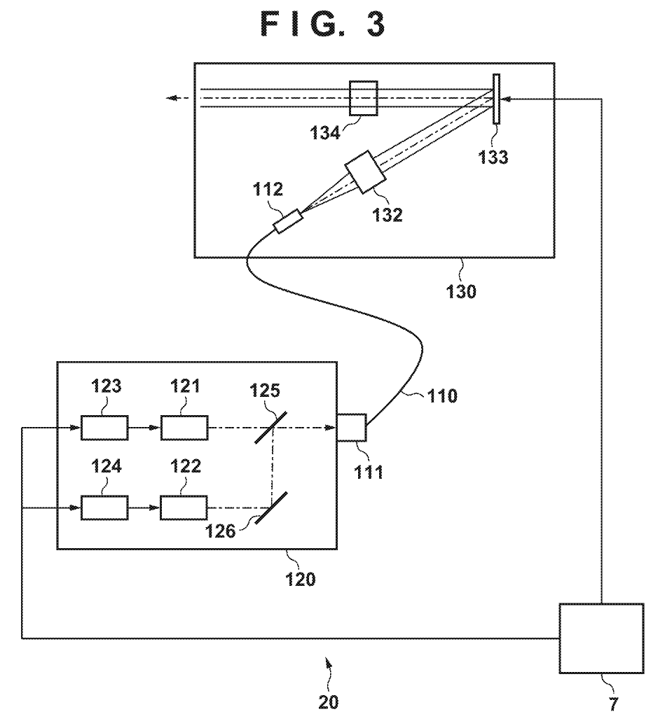

FIG. 3 is a schematic view illustrating an example of the configuration of the light source unit 20. The light source unit 20 includes a first light source 121 that generates first light having a first wavelength range for generating the first modulated light, and a second light source 122 that generates second light having a second wavelength range for generating the second modulated light. The light source unit 20 further includes a digital mirror device (DMD) 133 that is a spatial light modulator that generates the first modulated light obtained by modulating the first light and the second modulated light obtained by modulating the second light. The light source unit 20 also includes mirrors 125 and 126, an incident part 111, and an optical system 132, which make the first light from the first light source 121 and the second light from the second light source 122 enter the DMD 133.

The light source unit 20 is formed by, for example, connecting an illumination unit 120 and a modulation unit 130 by an optical fiber 110. The illumination unit 120 includes the first light source 121, the second light source 122, a first controller 123, a second controller 124, and the mirrors 125 and 126. The optical path of the first light from the first light source 121 and the optical path of the second light from the second light source 122 are combined by the mirrors 125 and 126 and connected to the incident part 111 of the optical fiber 110. An emission part 112 of the optical fiber 110 is connected to the modulation unit 130.

The first controller 123 controls the first light source 121 under the control of the controller 7. Control of the first light source 121 includes control of turn-on (ON) and turn-off (OFF) of the first light source 121 and control of the intensity (illuminance) of the first light generated by the first light source 121. For example, the first controller 123 includes a constant current circuit that supplies, to the first light source 121, a current having a current value according to an instruction value from the controller 7. The first controller 123 includes a driving circuit that drives the first light source 121 in accordance with an instruction value, and a photoelectric conversion sensor that receives part of the first light generated by the first light source 121, and may have a configuration to feed back the output of the photoelectric conversion sensor to the driving circuit.

The second controller 124 controls the second light source 122 under the control of the controller 7. Control of the second light source 122 includes control of turn-on (ON) and turn-off (OFF) of the second light source 122 and control of the intensity (illuminance) of the second light generated by the second light source 122. For example, the second controller 124 includes a constant current circuit that supplies, to the second light source 122, a current having a current value according to an instruction value from the controller 7. The second controller 124 includes a driving circuit that drives the second light source 122 in accordance with an instruction value, and a photoelectric conversion sensor that receives part of the second light generated by the second light source 122, and may have a configuration to feed back the output of the photoelectric conversion sensor to the driving circuit.

The controller 7 individually controls the first light source 121 and the second light source 122 via the first controller 123 and the second controller 124. For example, the controller 7 controls the first light source 121 and the second light source 122 such that when turning on one of the first light source 121 and the second light source 122, the other is turned off. In another point of view, when one of the first light from the first light source 121 and the second light from the second light source 122 enters the DMD 133, the other of the first light and the second light does not enter the DMD 133. This is implemented by, for example, controlling the first light source 121 and the second light source 122 by the first controller 123 and the second controller 124, or a mechanism that selectively blocks one of the first light and the second light.

Here, an example of wavelength assignment for the curing light 9, the illumination light 15, the observation light 18, and the modulated light 21 (the first modulated light and the second modulated light) will be described. The curing light 9 is light that cures the imprint material IM and has an arbitrary wavelength range within the range of 300 nm to 380 nm but may have a wavelength range of 300 nm or less.

The illumination light 15 is light for detecting (illuminating) the alignment mark, and has a wavelength range of 550 nm to 750 nm.

The observation light 18 is light for observing (obtaining) the contact state between the imprint material IM and the mold M, the filling state of the imprint material IM with respect to the space between the substrate S and the mold M, and the like. For the observation light 18, for example, a wavelength range not overlapping the wavelength ranges of the curing light 9 and the illumination light 15 is selected from the wavelength range of 400 nm to 480 nm.

The modulated light 21 includes the first modulated light having a wavelength range the imprint material IM is cured, and the second modulated light having a wavelength range where the imprint material IM is not cured. For the modulated light 21, a wavelength range similar to that of the observation light 18, for example, a wavelength range not overlapping the wavelength ranges of the curing light 9 and the illumination light 15 is selected from the wavelength range of 400 nm to 480 nm. The first modulated light is generated by modulating, by the modulation unit 130 (DMD 133), the first light generated by the first light source 121. The second modulated light is generated by modulating, by the modulation unit 130 (DMD 133), the second light generated by the second light source 122.

The wavelength of the first light generated by the first light source 121 and the wavelength of the second light generated by the second light source 122 can be selected (decided) from the upper limit of the wavelength range where the imprint material IM is cured. For example, if the upper limit of the wavelength range where the imprint material IM is cured is 440 nm, the wavelength of the first light generated by the first light source 121 can be set to about 410 nm, and the wavelength of the second light generated by the second light source 122 can be set to about 460 nm. Each of the first light source 121 and the second light source 122 is preferably a light source that generates single wavelength light having a short wavelength width and, for example, a laser diode is suitably used. The laser diode is superior in that it can be quickly switched between turn-on and turn-off. Note that the first light source 121 and the second light source 122 may be formed by variable wavelength light sources that can change the wavelengths of the first light and the second light.

Light transmitted to the modulation unit 130 via the optical fiber 110 enters the DMD 133 serving as a spatial light modulator via the optical system 132. The optical system 132 includes, for example, a condensing optical system and an illumination system (for example, a microlens array) that uniformizes the light from the condensing optical system and illuminates the DMD 133. The DMD 133 includes a plurality of micromirrors (not shown) that reflect light, and a plurality of actuators that respectively drive the plurality of micromirrors. In accordance with an instruction from the controller 7, each actuator sets a corresponding micromirror to an angle of -12° (ON state) or +12° (OFF state) with respect to the array plane of the plurality of micromirrors. The light reflected by the micromirror in the ON state serves as the modulated light and forms an image on the substrate S via an optical system 134 (projection optical system) that sets the DMD 133 and the substrate S in a conjugate relationship with the optical system. The light reflected by the micromirror in the OFF state is reflected to a direction of not reaching the substrate S. The region (maximum irradiation region) projected to the substrate S when all the micromirrors are set in the ON state is larger than the size of the maximum pattern formation region of the substrate S. The DMD 133 can be replaced with another spatial light modulator, for example, a liquid crystal display (LCD).

The optical system forming the modulation unit 130 needs to transmit both the first light (first modulated light) having the wavelength that cures the imprint material IM and the second light (second modulated light) having the wavelength that does not cure the imprint material IM. Also, in a general DMD, at a wavelength of 420 nm or less, the maximum light intensity that can be applied to the micromirror array decreases. Furthermore, at a wavelength near 400 nm, which is the boundary between ultraviolet light and visible light, the maximum light intensity that can be applied to the micromirror array extremely decreases to about 1/1000. Therefore, it is desirable to use a laser diode or the like having a short wavelength width to bring the wavelength of the first light and the wavelength of the second light close to the upper limit of the wavelength range where the imprint material IM is cured.

For example, based on the light intensity distribution (illuminance distribution) to be formed on the substrate S, the controller 7 controls switching between the ON state and the OFF state of each micromirror of the DMD 133. The control of switching includes, for example, control concerning the time of setting each micromirror in the ON state and control concerning the time of setting each micromirror in the OFF state. The larger the number of micromirrors in the ON state is and the longer the time in the ON state is, the larger the exposure amount that can be applied to the shot region of the substrate S is.

The controller 7 includes a memory that stores light intensity distribution data used to generate the first modulated light by modulating the first light, and light intensity distribution data used to generate the second modulated light by modulating the second light. The light intensity distribution data used to generate the first modulated light by modulating the first light includes light intensity distribution data for increasing the viscosity of the imprint material IM in an arbitrary portion of the shot region of the substrate S to increase the bonding force between the substrate S and the mold M via the imprint material IM.

The configuration in which the modulation unit 130 is shared by the first light source 121 and the second light source 122 is advantageous in miniaturizing the modulation unit 130 or the light source unit 20 and accordingly simplifying the structure of the imprint apparatus 1. This facilitates arrangement of the modulation unit 130 near the optical path LP. The configuration in which the illumination unit 120 and the modulation unit 130 are separated from each other is advantageous in arranging the illumination unit 120 that is a heat source at a position far from the optical path LP of the imprint apparatus 1. Note that the illumination unit 120 and the modulation unit 130 may be arranged close to each other without using the optical fiber 110. Also, the illumination unit 120 may be incorporated in the modulation unit 130. Furthermore, the first light source 121 and the modulation unit 130 may be connected by a first optical fiber, and the second light source 122 and the modulation unit 130 may be connected by a second optical fiber. In this case, the optical path of the first light emitted from the first optical fiber and the optical path of the second light emitted from the second optical fiber are coupled.

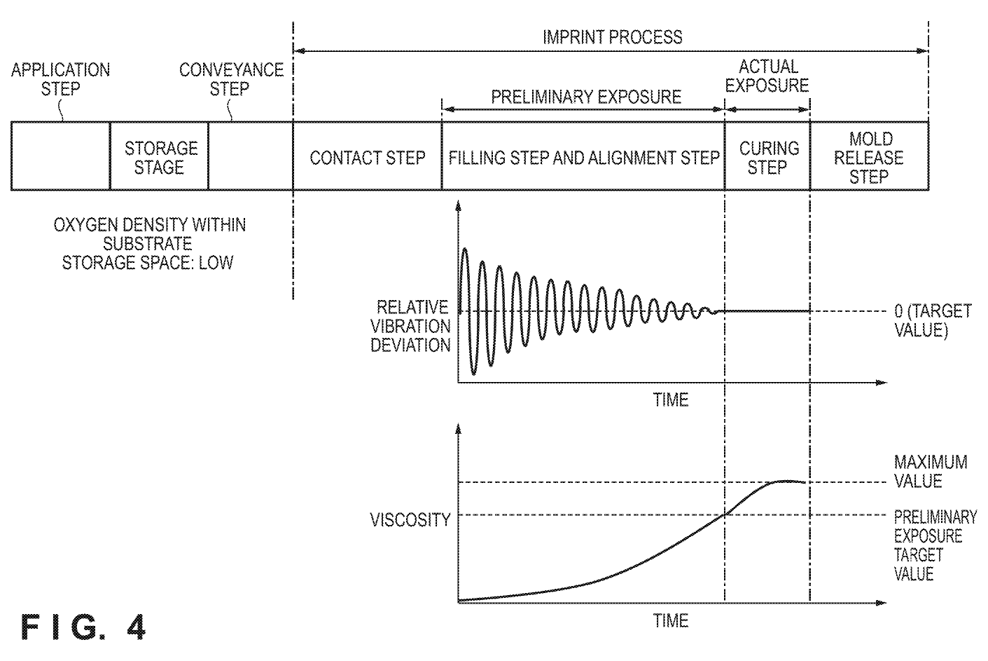

The imprint process performed by the imprint apparatus 1, more specifically, (a variation of) a relative vibration between the mold M and the substrate S in a contact state in which the mold M and the imprint material IM on the substrate S are in contact will be described with reference to FIG. 4. As shown in FIG. 4, the imprint process includes a contact step, an alignment step, a curing step, and a mold release step.

As described above, the contact step is a step of bringing the imprint material IM on the substrate S and (the pattern region PR of) the mold M into contact with each other by the driving mechanism DRV. The contact step corresponds to a period that starts when the imprint material IM on the substrate S and the pattern region PR of the mold M deformed into a convex shape contact and ends when the entire pattern region PR is returned to a flat state.

In the alignment step, based on the measurement result of the position measuring unit 12, at least one of the substrate S and the mold M is driven by the driving mechanism DRV to align the pattern region PR of the mold M and the shot region of the substrate S with each other. Also, in the alignment step, based on the measurement result of the position measuring unit 12, the mold M is deformed by the mold driving mechanism to align the pattern region PR of the mold M and the shot region of the substrate S with each other.

A filling step progresses in parallel to the alignment step. In the filling step, the imprint material IM between the substrate S and the pattern region PR of the mold M is filled into a concave portion forming the pattern of the pattern region PR, and a space (gap) existing between the substrate S and the pattern region PR of the mold M disappears. The alignment step and the filling step are shown as "filling step and alignment step" in FIG. 4, and in an example, the filling step is started prior to the alignment step.

Preliminary exposure is performed in parallel to the alignment step (or the filling step), as shown in FIG. 4. As described above, in the preliminary exposure, the imprint material IM is irradiated with the first modulated light from the light source unit 20, thereby increasing the viscosity of the imprint material IM in an arbitrary portion of the shot region of the substrate S.

Also, in this embodiment, as the preprocess of the imprint process, an application step, a storage step, and a conveyance step are performed, as shown in FIG. 4. The application step is a step of forming at least one layer including an underlying layer or an adhesion layer on the substrate S by the application apparatus 100. Note that the at least one layer formed on the substrate S will be referred to as an "underlying layer" hereinafter. The storage step is a step of containing and storing the substrate S with the underlying layer formed thereon in the substrate storage space 1200 after the application step and before the substrate S is conveyed to the imprint apparatus 1. The conveyance step is a step of conveying the substrate S stored in the substrate storage space 1200 to the imprint apparatus 1 after the storage step.

Curing of the imprint material IM occurs when a polymerizable compound causes a polymerization reaction by a radical generated by a photopolymerization initiator irradiated with light. Oxygen reacts with the radical generated by the photopolymerization initiator upon light irradiation, thereby eliminating the radical. This impedes the polymerization reaction of the polymerizable compound. This means that curing of the imprint material IM is impeded.

In the storage step, oxygen may exist inside the substrate storage space 1200 (in the substrate storage space) in which the substrate S is stored. In this case, the oxygen is occluded in the underlying layer formed on the substrate S stored in the substrate storage space 1200. The oxygen occluded in the underlying layer is diffused to the imprint material IM arranged on the underlying layer. In preliminary exposure, this is a factor to impede (increase of the viscosity in) curing of the imprint material IM and reduce curing in the preliminary exposure. Note that in this embodiment, oxygen will be described as an example of a gas (type) that impedes the polymerization reaction of the polymerizable compound, that is, curing of the imprint material IM, but the gas is not limited to this. In other words, oxygen here can be understood as a concept broadly including a gas (type) that impedes curing of the imprint material IM.

Here, if the density of oxygen existing in the substrate storage space 1200 is low, the amount (oxygen occlusion amount) of oxygen occluded in the underlying layer is small. In this case, as shown in FIG. 4, (the deviation of) the relative vibration between the mold M and the substrate S can be suppressed to a target value (for example, "0") by the preliminary exposure during the filling step and alignment step. This is because impediment of curing of the imprint material IM caused by oxygen occluded in the underlying layer is weak, and the viscosity of the imprint material IM can be increased to the preliminary exposure target value by the preliminary exposure. Note that the preliminary exposure target value is set to a value lower than the viscosity of the imprint material IM necessary for completely curing the imprint material IM in the curing step (actual exposure), that is, the maximum value of viscosity.

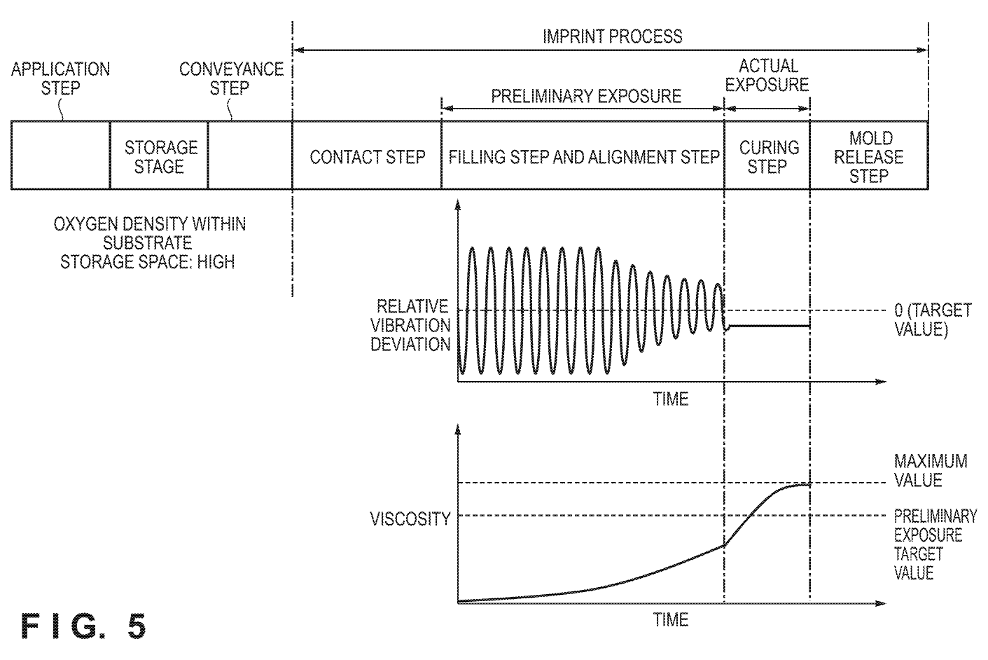

On the other hand, when the density of oxygen existing in the substrate storage space 1200 becomes high, the amount of oxygen occluded in the underlying layer increases. In this case, as shown in FIG. 5, (the deviation of) the relative vibration between the mold M and the substrate S cannot be suppressed to the target value (for example, "0") by the preliminary exposure during the filling step and alignment step. This is because impediment of curing of the imprint material IM caused by oxygen occluded in the underlying layer is strong, and the viscosity of the imprint material IM cannot be increased to the preliminary exposure target value by the preliminary exposure. If the relative vibration between the mold M and the substrate S cannot sufficiently be reduced, the alignment accuracy between the mold M and the substrate S lowers.

In this embodiment, there is provided a technique of controlling, in accordance with the type or density of a gas in the substrate storage space, exposure (preliminary exposure and actual exposure) of irradiating the imprint material IM with light in a state in which the imprint material IM on the substrate S and the mold M are in contact. According to this technique, it is possible to reduce the influence of impediment of curing of the imprint material IM and suppress lowering of the alignment accuracy between the mold M and the substrate S.

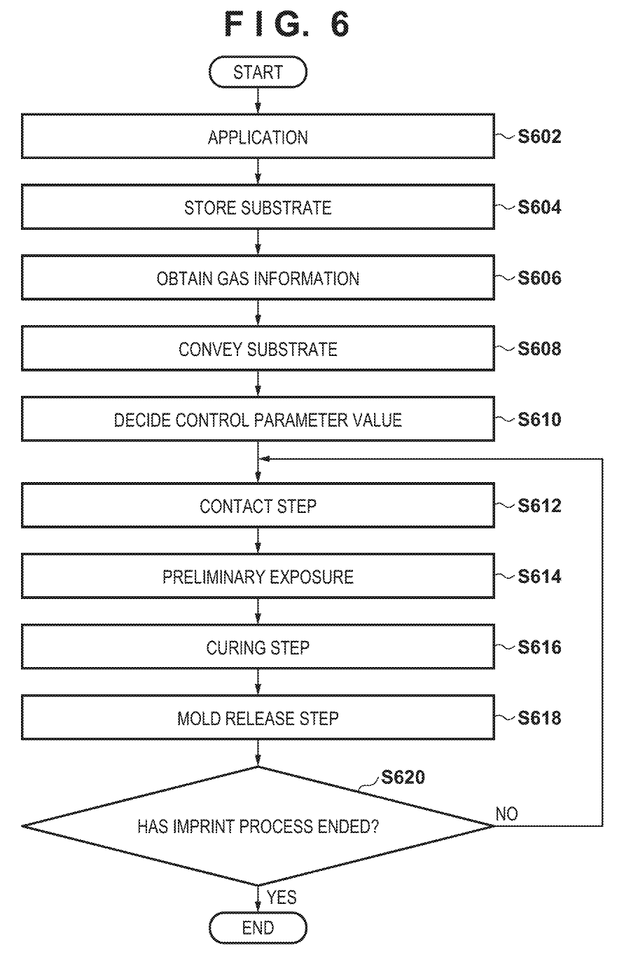

The operation of the imprint system 1000 will be described with reference to FIG. 6. This operation includes the application step to the mold release step and is executed by generally controlling the application apparatus 100 by the control apparatus 300 and the units of the imprint apparatus 1 by the controller 7. Note that preliminary exposure will be described below as an example of exposure of irradiating the imprint material IM with light in a state in which the imprint material IM on the substrate S and the mold M are in contact. However, the present disclosure can also be applied to actual exposure that is exposure of irradiating the imprint material IM with light in a state in which the imprint material IM on the substrate S and the mold M are in contact.

In step S602, in the application apparatus, at least one layer including an underlying layer or an adhesion layer is formed (applied) on the substrate S.

In step S604, the substrate S with the at least one layer formed thereon in step S602 is contained and stored in the substrate storage space 1200.

In step S606, gas information about the gas in the substrate storage space in which the substrate S is stored in step S604, for example, the type and density of the gas in the substrate storage space are obtained using the gas detector 1100. Thus, step S606 is a step (first step) of obtaining gas information about the gas in the storage space in which the substrate S with the at least one layer formed thereon is stored.

In step S608, the substrate S stored in the substrate storage space 1200 is conveyed to the imprint apparatus 1 via a substrate conveyance mechanism (not shown).

In step S610, in accordance with the gas information obtained in step S606, for example, the type and density of the gas in the substrate storage space, the controller 7 decides the value of a control parameter for controlling preliminary exposure as a set condition (exposure condition) concerning preliminary exposure. The control parameter is a parameter concerning control of light (the modulated light 21 in preliminary exposure or the curing light 9 in actual exposure) with which the imprint material IM is irradiated in a state in which the imprint material IM on the substrate S and the mold M are in contact. The control parameter includes at least one of the illuminance, irradiation time, and wavelength of the light to irradiate the imprint material IM. For example, if the gas in the substrate storage space is oxygen and its density is high, in the preliminary exposure, the illuminance of light to irradiate the imprint material IM is made high and/or the irradiation time of light to irradiate the imprint material IM is made long. Thus, step S610 is a step (second step) of deciding the value of the control parameter for controlling exposure, including preliminary exposure and actual exposure, of irradiating the imprint material IM with light based on the gas information about the gas in the substrate storage space. Also, in this embodiment, the controller 7 functions as a decision unit that decides the value of the control parameter. Note that in step S610, the set condition, that is, the value of the control parameter concerning preliminary exposure may be adjusted in accordance with the material or film thickness of the at least one layer such as an underlying layer or an adhesion layer formed on the substrate S. To reduce the relative vibration between the mold M and the substrate S, the value of the control parameter may be decided by combining these.

In step S612, the contact step of bringing the imprint material IM on the substrate S and the mold M into contact with each other is performed.

In step S614, the controller 7 performs preliminary exposure of increasing the viscosity of the imprint material IM by irradiating it with the first modulated light from the light source unit 20 in accordance with the value of the control parameter decided in step S606. For example, to control the illuminance or irradiation time of the first modulated light to irradiate the imprint material IM, the DMD 133 is used. To control the wavelength of the first modulated light to irradiate the imprint material IM, the first light source 121 formed by a variable wavelength light source is used. In this embodiment, since the preliminary exposure is performed in accordance with the value of the control parameter decided based on the gas information about the gas in the substrate storage space, the viscosity of the imprint material IM can be increased to the preliminary exposure target value. Hence, the relative vibration between the mold M and the substrate S can sufficiently be reduced, and lowering of the alignment accuracy between the mold M and the substrate S can be suppressed in the alignment step that is performed in parallel to the preliminary exposure. Thus, step S614 is a step (third step) of performing exposure of irradiating the imprint material IM with light in accordance with the decided value of the control parameter. Also, in this embodiment, the controller 7 functions as a processing unit that performs preliminary exposure.

In step S616, the controller 7 performs the curing step (actual exposure) of curing the imprint material IM by irradiating the imprint material IM with the curing light 9 from the curing light source unit 2 in accordance with the value of the control parameter for controlling the actual exposure, which is the set condition (exposure condition) concerning actual exposure. Thus, step S616 is a step of performing exposure of irradiating the imprint material IM with light in accordance with the value of the control parameter. Also, in this embodiment, the controller 7 functions as a processing unit that performs actual exposure.

In step S618, the mold release step of separating the mold M from the imprint material IM cured in step S616 is performed.

In step S620, it is determined whether the imprint process is ended for all shot regions of the substrate S. If the imprint process is not ended for all shot regions, the process returns to step S612 to perform the imprint process for the next shot region. On the other hand, if the imprint process is ended for all shot regions, the operation of the imprint system 1000 is ended.

As described above, in this embodiment, in preliminary exposure, at least one of the illuminance, irradiation time, and wavelength of the light to irradiate the imprint material IM is controlled in accordance with (the type and density of) the gas in the substrate storage space such that the relative vibration between the mold M and the substrate S is reduced. Thus, since the viscosity of the imprint material IM is increased to the preliminary exposure target value in the alignment step that is performed in parallel to the preliminary exposure, the mold M and the substrate S can accurately be aligned with each other, and lowering of the alignment accuracy can be suppressed.

Note that depending on the type or density of the gas in the substrate storage space, it may be impossible to decide (calculate) the illuminance, irradiation time, and/or wavelength of light (the value of the control parameter) capable of increasing the viscosity of the imprint material IM to the preliminary exposure target value. In this case, it is preferable that adjustment is performed to obtain the illuminance, irradiation time, and/or wavelength of light capable of increasing the viscosity of the imprint material IM to maximum and preliminary exposure is then performed. Then, it is preferable to, for example, make a notification indicating that the viscosity of the imprint material IM is not sufficiently increased in preliminary exposure via the user interface UIF, that is, display the notification on the user interface UIF.

When performing the imprint process for a substrate stored in a substrate storage space different from the substrate storage space 1200, the value of the control parameter, which is the set condition concerning preliminary exposure, is changed in accordance with gas information about a gas in the different substrate storage space.

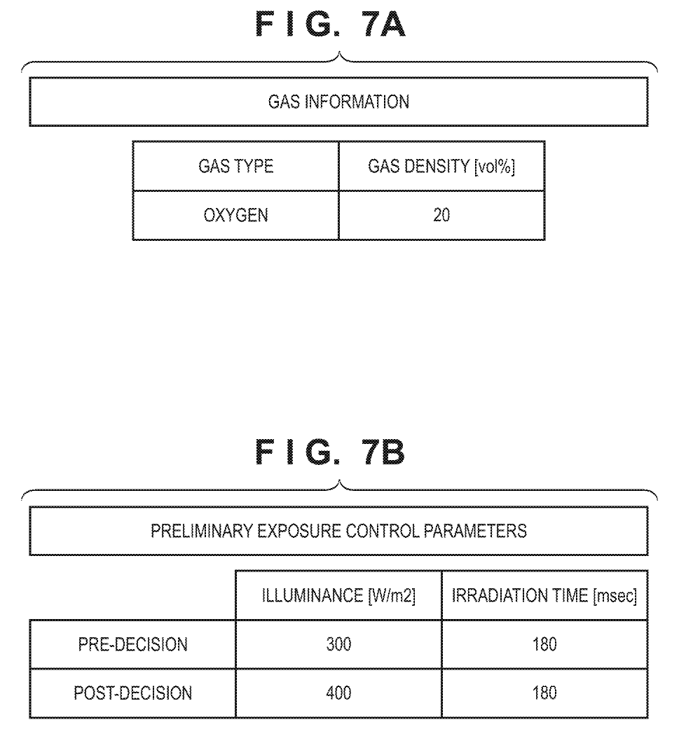

The gas information obtained in step S606 by the gas detector 1100 arranged in the substrate storage space 1200 may be displayed on the user interface UIF as information to be provided to the user. For example, as shown in FIG. 7A, the controller 7 controls such that the type of the gas and the density of the gas are displayed on the user interface UIF as the gas information obtained from the gas detector 1100. FIG. 7A is a view showing an example of gas information displayed on the user interface UIF. Also, if the user knows the gas information about the gas in the substrate storage space, the user interface UIF may be configured to accept a user operation of inputting the gas information. In this case, the controller 7 may obtain the gas information about the gas in the substrate storage space via the user interface UIF.

Similarly, the value of the control parameter decided by the controller 7 in step S610 may be displayed on the user interface UIF as information to be provided to the user. For example, as shown in FIG. 7B, the controller 7 controls such that the illuminance and irradiation time of light to irradiate the imprint material IM are displayed on the user interface UIF as the value of the control parameter for controlling preliminary exposure. In addition, the controller 7 preferably controls such that together with the value of the control parameter decided in step S610, a preceding value of the control parameter is displayed on the user interface UIF, as shown in FIG. 7B. This allows the user to easily know how the value of the control parameter was updated (changed) in accordance with the gas in the substrate storage space. It can also be considered that the user finely adjusts the value of the control parameter decided in accordance with the gas in the substrate storage space (for example, makes the illuminance low and the irradiation time long). In this case, the user interface UIF is configured to accept a user operation of adjusting the value of the control parameter. FIG. 7B is a view showing an example of the values of control parameters displayed on the user interface UIF.

The pattern of a cured product formed using the imprint apparatus 1 (imprint system 1000) in the embodiment is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

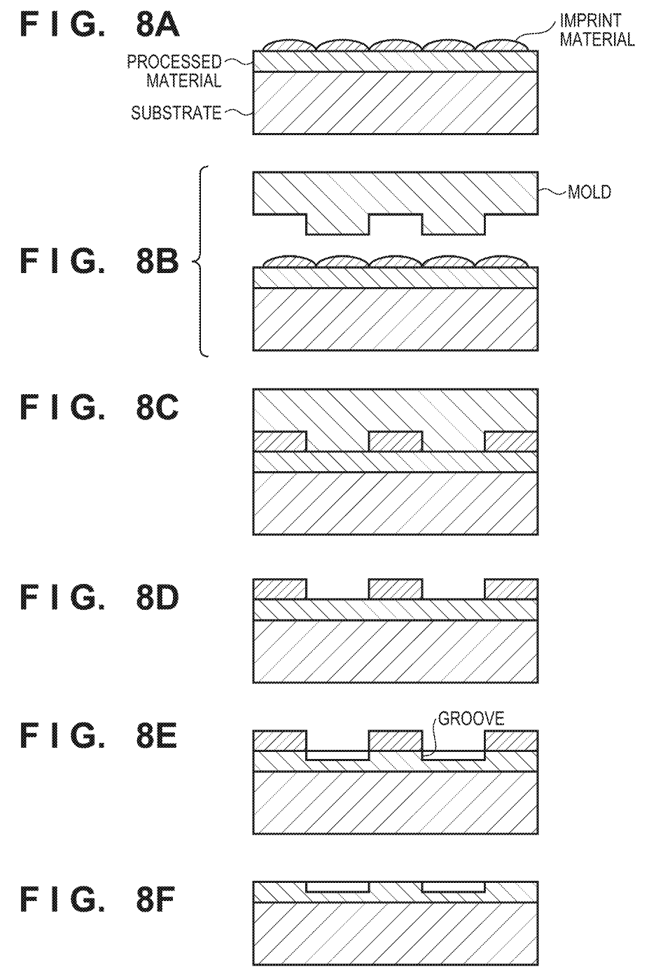

Next, description regarding a detailed method of manufacturing an article is given. As illustrated in FIG. 8A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 8B, a side of the mold for imprint with a projection and groove pattern is formed on and caused to face the imprint material on the substrate. As illustrated in FIG. 8C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 8D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 8E, when etching is performed using the pattern of the cured product as an etching resistant mask, a portion of the surface of the processed material where the cured product does not exist or remains thin is removed to form a groove. As shown in FIG. 8F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent application No. 2024-190073 filed on October 29, 2024, which is hereby incorporated by reference herein in its entirety.

What is claimed is:

1. An imprint method of forming, using a mold, a pattern on an imprint material arranged on at least one layer formed on a substrate, comprising:
obtaining gas information about a gas in a storage space that stores the substrate;
deciding, based on the gas information obtained in the obtaining, a value of a control parameter for controlling exposure of irradiating the imprint material with light in a state in which the mold and the imprint material on the at least one layer on the substrate stored in the storage space are in contact; and
performing the exposure in accordance with the value of the control parameter decided in the deciding.

2. The method according to claim 1, wherein
the exposure includes:
preliminary exposure of irradiating the imprint material with light to increase a viscosity of the imprint material before curing the imprint material; and
actual exposure of irradiating the imprint material with light to cure the imprint material after the preliminary exposure.

3. The method according to claim 2, wherein
in the deciding, the value of the control parameter for controlling the preliminary exposure is decided, and
in the performing, the preliminary exposure is performed.

4. The method according to claim 3, wherein
the preliminary exposure is performed in the state in parallel to alignment between the mold and the substrate.

5. The method according to claim 1, wherein
in the obtaining, the gas information is obtained by detecting the gas using a gas detector arranged in the storage space.

6. The method according to claim 1, wherein
the gas information includes a type of the gas and a density of the gas.

7. The method according to claim 6, wherein
the gas includes oxygen.

8. The method according to claim 1, wherein
the control parameter includes at least one of an illuminance, an irradiation time, and a wavelength of the light to irradiate the imprint material.

9. The method according to claim 1, further comprising displaying, on a user interface, the gas information obtained in the obtaining.

10. The method according to claim 1, further comprising displaying, on a user interface, the value of the control parameter decided in the deciding.

11. The method according to claim 1, wherein
the at least one layer contains spin on carbon.

12. An imprint apparatus for forming, using a mold, a pattern on an imprint material arranged on at least one layer formed on a substrate, comprising:
an obtaining unit configured to obtain gas information about a gas in a storage space that stores the substrate;
a decision unit configured to decide, based on the gas information obtained by the obtaining unit, a value of a control parameter for controlling exposure of irradiating the imprint material with light in a state in which the mold and the imprint material on the at least one layer on the substrate stored in the storage space are in contact; and
a processing unit configured to perform the exposure in accordance with the value of the control parameter decided by the decision unit.

13. The apparatus according to claim 12, further comprising a user interface configured to display the gas information and the value of the control parameter.

14. The apparatus according to claim 13, wherein the user interface accepts a user operation of adjusting the value of the control parameter.

15. An article manufacturing method comprising:
forming a pattern on a substrate using an imprint method defined in claim 1;
processing the substrate on which the pattern is formed in the forming; and
manufacturing an article from the processed substrate.
